(19) United States
(12) Patent Application Publication
(10) Pub. No.: US 2006/0281255 A1
(43) Pub. Date: Dec. 14, 2006

(54) Method for forming a sealed storage non-volative multiple-bit memory cell

(76) Inventors: Chun-Jen Chiu, Hsinchu (TW); Kuang-Wen Liu, Hsinchu (TW); Hsin-Huei Chen, Hsinchu (TW); Jen-Ren Huang, Hsinchu (TW)

Correspondence Address: Kenton R. Mullins;Stout, Uxa, Buyan & Mullins, LLP, Suite 300, 4 Venture, Irvine, CA, 92618, US

(21) Appl. No.: 11/153,690

(22) Filed: Jun. 14, 2005

(51) Int. Cl. H01L 21/336

(52) U.S. Cl. 438/257

(57) ABSTRACT

A method of fabricating an array of trapped charge memory cells is described that eliminates bird's beak issues. Implants at a tilt angle form pockets in a substrate that reduce problems resulting from a short channel effect.

### BACKGROUND OF THE INVENTION

1. Field of the Invention

The present invention relates generally to non-volatile memory devices and, more particularly, to localized trapped charge memory cell structures capable of storing multiple bits per cell.

2. Description of Related Art

A non-volatile semiconductor memory device is designed to maintain programmed information even in the absence of electrical power. Read only memory (ROM) is a non-volatile memory commonly used in electronic equipment such as microprocessor-based digital electronic equipment and portable electronic devices such as cellular phones.

ROM devices typically include multiple memory cell arrays. Each memory cell array may be visualized as including intersecting word lines and bit lines. Each word and bit line intersection can correspond to one bit of memory. In mask programmable metal oxide semiconductor (MOS) ROM devices, the presence or absence of a MOS transistor at word and bit line intersections distinguishes between a stored logic ‘0’ and logic ‘1’.

A programmable read only memory (PROM) is similar to the mask programmable ROM except that a user may store data values (i.e., program the PROM) using a PROM programmer. A PROM device is typically manufactured with fusible links at all word and bit line intersections. This corresponds to having all bits at a particular logic value, typically logic ‘1’. The PROM programmer is used to set desired bits to the opposite logic value, typically by applying a high voltage that vaporizes the fusible links corresponding to the desired bits. A typical PROM device can only be programmed once.

An erasable programmable read only memory (EPROM) is programmable like a PROM, but can also be erased (e.g., to an all logic ‘1’s state) by exposing it to ultraviolet light. A typical EPROM device has a floating gate MOS transistor at all word and bit line intersections (i.e., at every bit pair location). Each MOS transistor has two gates: a floating gate and a non-floating gate. The floating gate is not electrically connected to any conductor, and is surrounded by a high impedance insulating material. To program the EPROM device, a high voltage is applied to the non-floating gate at each bit location where a logic value (e.g., a logic ‘0’) is to be stored. This causes a breakdown in the insulating material and allows a negative charge to accumulate on the floating gate. When the high voltage is removed, the negative charge remains on the floating gate. During subsequent read operations, the negative charge prevents the MOS transistor from forming a low resistance channel between a drain terminal and a source terminal (i.e., from turning on) when the transistor is selected.

An EPROM integrated circuit is normally housed in a package having a quartz lid, and the EPROM is erased by exposing the EPROM integrated circuit to ultraviolet light passed through the quartz lid. The insulating material surrounding the floating gates becomes slightly conductive when exposed to the ultraviolet light, allowing the accumulated negative charges on the floating gates to dissipate.

A typical electrically erasable programmable read only memory (EEPROM) device is similar to an EPROM device except that individual stored bits may be erased electrically. The floating gates in the EEPROM device are surrounded by a much thinner insulating layer, and accumulated negative charges on the floating gates can be dissipated by applying a voltage having a polarity opposite that of the programming voltage to the non-floating gates.

Flash memory devices are sometimes called flash EEPROM devices, and differ from EEPROM devices in that electrical erasure involves large sections of, or the entire contents of, a flash memory device.

A relatively recent development in non-volatile memory is localized trapped charge devices. While these devices are commonly referred to as nitride read only memory (NROM) devices, the acronym “NROM” is a part of a combination trademark of Saifun Semiconductors Ltd. (Netanya, Israel).

Performance of localized trapped charge devices may be degraded by effects that are introduced during fabrication of memory cells. One such effect, which has been referred to as a “bird's beak” effect, arises from oxidation that may inevitably occur after a memory cell is formed. FIGS. 1A and 1B illustrate this bird's beak effect. FIG. 1A shows a portion of an array comprising a pair of localized trapped charge memory cells formed on a substrate 100. Each memory cell comprises a first oxide layer 105 formed on the substrate 100 and a nitride layer 110 formed on the first oxide layer 105. A second oxide layer 115 is formed on the nitride layer, and an electrically conductive gate 120 is formed on the second oxide layer 115. A buried source/drain region 125 that comprises a bit line for the array is formed in the substrate 100 between the two memory cell structures. According to a known fabrication method, a relatively thick oxide layer 130 is grown over the source/drain region 125 to electrically isolate the buried source/drain region 125 from a subsequently-formed word line (not shown).

FIG. 1B illustrates a problem that arises in known localized trapped charge memory structures of the type illustrated in FIG. 1A. The thick oxide layer 130 formed over the buried source/drain region 125 may encroach into two areas of the localized trapped charge memory cell structures where data is stored, potentially reducing data retention time and a maximum number of read/write cycles (i.e., endurance) of the memory cell structures.

The depiction of FIG. 1B is a magnified view of a portion 135 of FIG. 1A where the first oxide layer 105, the buried source/drain region 125, and the thick oxide layer 130 meet. When the thick oxide layer 130 is grown over the buried source/drain region 125, a pointed bird's beak structure 127 may form at an outer edge of the thick oxide layer 130 and the junction of the first oxide layer 105, the buried source/drain region 125, and the thick oxide layer 130.

Typically, a localized trapped charge memory cell stores one bit of data in the area of the first oxide layer 105 shown in FIG. 1B. The bird's beak structure 127 may extend a significant distance under the first oxide layer 105 where it may reduce the data retention time and the endurance of the corresponding portion of the localized trapped charge memory cell structure. The bird's beak effect further may contribute to undesirable shortening of the effective length of a channel in the memory cell.

In addition to the bird's beak effect, bit lines formed in arrays of memory cells may exhibit relatively large resistances, thereby producing correspondingly large voltage drops within memory cells and increasing the power dissipated in the cells during programming. Both effects may act to reduce the utility of localized trapped charge devices.

A need thus exists in the prior art for methods of fabricating localized trapped charge memory devices having reduced bird's beak effects. A further need exists for methods of fabricating arrays of these memory devices with low bit line resistances.

### SUMMARY OF THE INVENTION

The present invention addresses these needs by providing a method of fabricating localized charge memory devices having a reduced bird's beak effect. An implementation of the method of the present invention produces arrays of localized charge memory devices having relatively low bit line resistances.

An implementation of the present invention comprises a method for forming an array of trapped charge memory cells. This implementation may comprise providing a semiconductor substrate having an oxide-nitride-oxide (ONO) layer formed on a surface thereof. A first layer of polysilicon may be deposited over the ONO layer, and a portion of the first layer of polysilicon may be removed in a reference direction, thereby forming at least one gate structure while exposing a portion of the ONO layer. An oxide spacer may be deposited on sides of the at least one gate structure of the ONO layer, and a portion of the ONO layer not covered by the oxide spacer may be removed, thereby exposing a portion of the substrate. At least one bit line may be formed in the exposed portion of the substrate. In another implementation of the method of the present invention, the removing of a portion of the first layer of polysilicon is followed by implanting with a tilt angle an implant pocket into the substrate through the ONO layer.

While the apparatus and method has or will be described for the sake of grammatical fluidity with functional explanations, it is to be expressly understood that the claims, unless expressly formulated under 35 U.S.C. 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 U.S.C. 112 are to be accorded full statutory equivalents under 35 U.S.C. 112.

Any feature or combination of features described herein are included within the scope of the present invention provided that the features included in any such combination are not mutually inconsistent as will be apparent from the context, this specification, and the knowledge of one skilled in the art. For purposes of summarizing the present invention, certain aspects, advantages and novel features of the present invention are described herein. Of course, it is to be understood that not necessarily all such aspects, advantages or features will be embodied in any particular embodiment of the present invention. Additional advantages and aspects of the present invention are apparent in the following detailed description and claims that follow.

### BRIEF DESCRIPTION OF THE FIGURES

FIGS. 1A and 1B illustrate a bird's beak effect in a prior art memory cell;

FIGS. 2A and 2B are flow diagrams that summarize an exemplary implementation of a method of fabricating trapped charge memory cells according to the present invention;

FIG. 3 is a cross-sectional diagram of a substrate on which is formed an oxide-nitride-oxide (ONO) layer.;

FIG. 4A is a plan view of the structure of FIG. 3 after polysilicon is deposited and etched along a Y-direction.

FIG. 4B is a cross-sectional view of the structure of FIG. 4A;

FIG. 5 is a cross-sectional view of the structure of FIG. 4B illustrating performing of pocket implantations;

FIG. 6 is a cross-sectional view of the structure of FIG. 5 illustrating formation of a shallow buried diffusion;

FIG. 7 is a cross-sectional view illustrating the effect of removing exposed portions of the ONO layer;

FIG. 8 is a cross-sectional view illustrating an n+ implantation forming source/drain regions;

FIGS. 9-11 are cross-sectional views illustrating formation of oxide layers;

FIG. 12A is a plan view illustrating removal of a portion of oxide and exposing gate surfaces;

FIG. 12B is a cross-sectional view of the structure of FIG. 12A;

FIG. 13A is a cross-sectional view of the structure of FIG. 12A after deposition of a polysilicon layer;

FIG. 13B is a plan view of the structure of FIG. 13A after removal of a portion of the polysilicon layer;

FIG. 14 is a cross-sectional view of the structure of FIG. 13B;

FIGS. 15 and 16 are cross-sectional views illustrating the deposition of oxide layers; and

FIG. 17 is a cross-sectional view illustrating the result of performing CMP on the structure of FIG. 16.

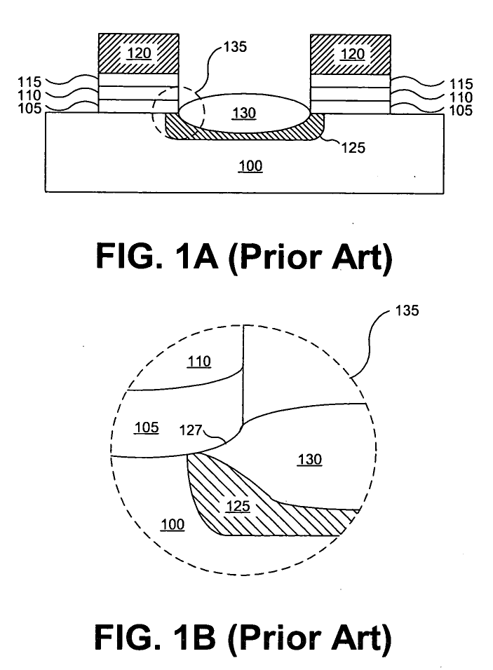

### DETAILED DESCRIPTION OF THE PRESENTLY PREFERRED EMBODIMENTS

Reference will now be made in detail to the presently preferred embodiments of the invention, examples of which are illustrated in the accompanying drawings. Wherever possible, the same or similar reference numbers are used in the drawings and the description to refer to the same or like parts. It should be noted that the drawings are in simplified form and are not to precise scale. In reference to the disclosure herein, for purposes of convenience and clarity only, directional terms, such as, top, bottom, left, right, up, down, over, above, below, beneath, rear, and front, are used with respect to the accompanying drawings. Such directional terms should not be construed to limit the scope of the invention in any manner.

Although the disclosure herein refers to certain illustrated embodiments, it is to be understood that these embodiments are presented by way of example and not by way of limitation. The intent of the following detailed description, although discussing exemplary embodiments, is to be construed to cover all modifications, alternatives, and equivalents of the embodiments as may fall within the spirit and scope of the invention as defined by the appended claims. It is to be understood and appreciated that the process steps and structures described herein do not cover a complete process flow for the manufacture of trapped charge memory devices. The present invention may be practiced in conjunction with various integrated circuit fabrication techniques that are conventionally used in the art, and only so much of the commonly practiced process steps are included herein as are necessary to provide an understanding of the present invention. The present invention has applicability in the field of semiconductor devices and processes in general. For illustrative purposes, however, the following description pertains to a method of fabricating trapped charge memory devices on a semiconductor substrate.

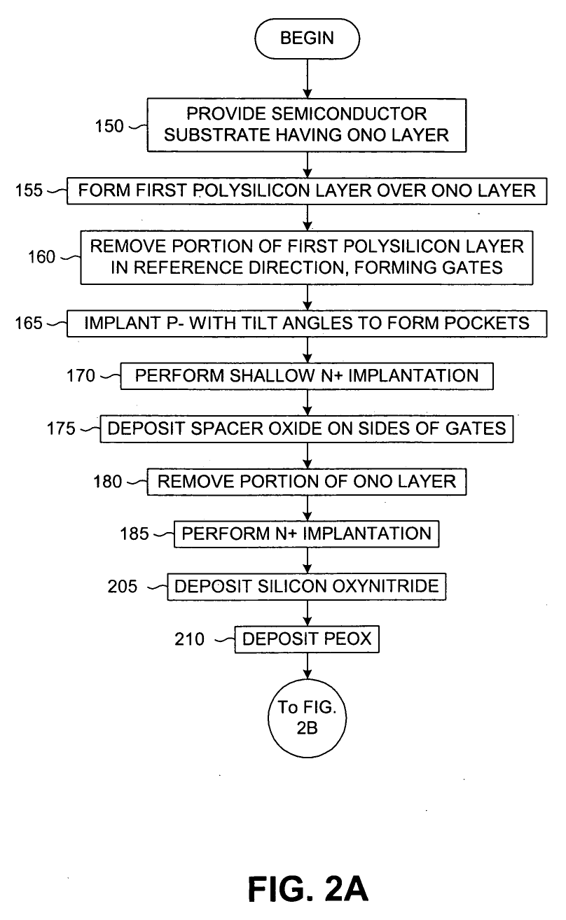

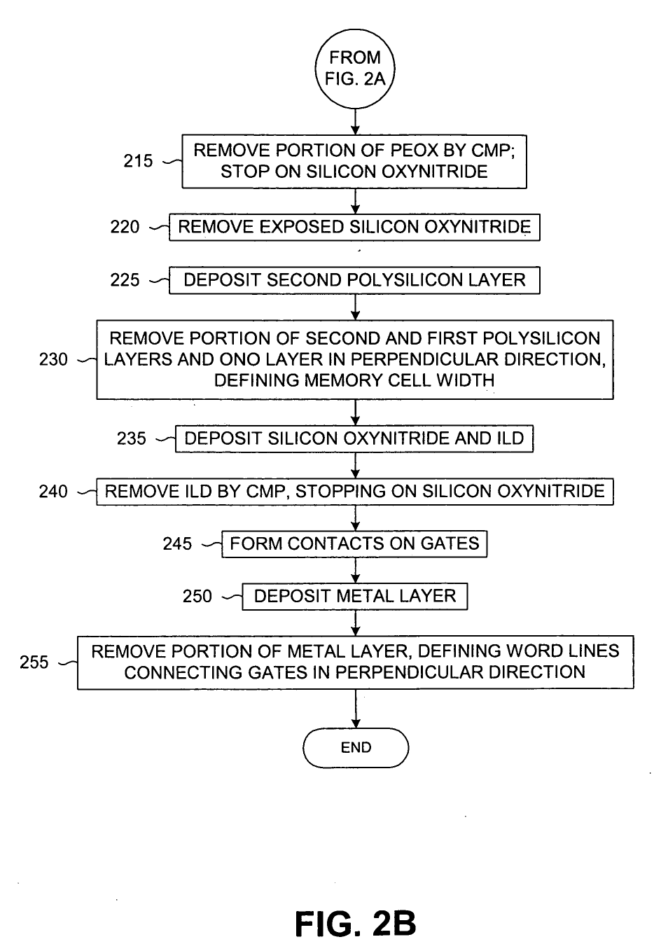

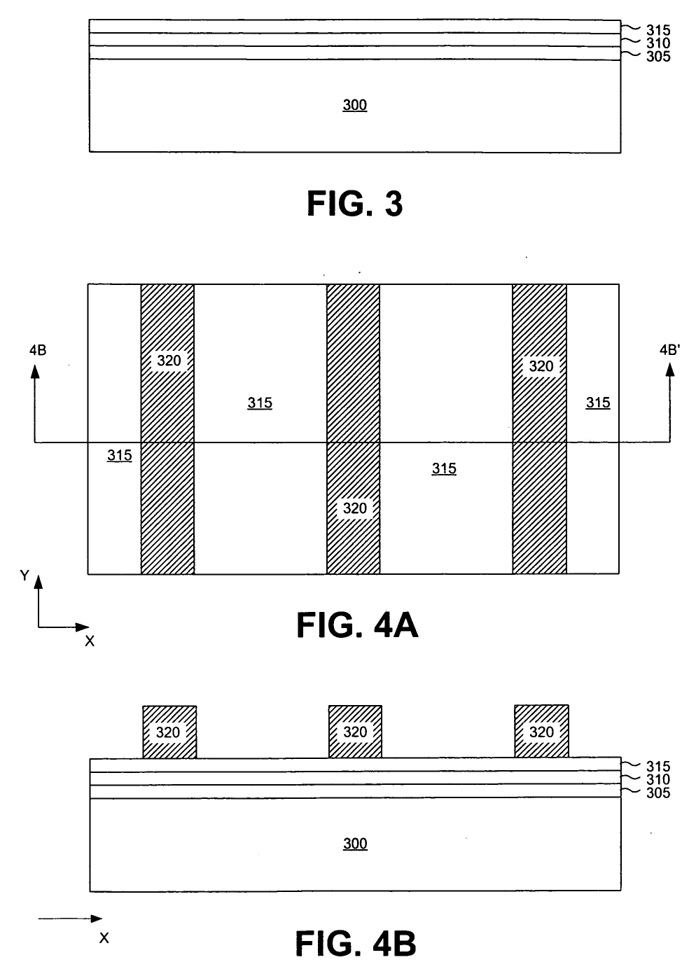

Referring to the drawings, FIGS. 2A and 2B present a flow diagram that summarizes aspects of an implementation of the method of the present invention. This implementation of the method will be described with reference to FIGS. 3-20. A semiconductor substrate 300 having an oxide-nitride-oxide (ONO) layer is provided at step 150 as illustrated in FIG. 3. The semiconductor substrate 300 may comprise intrinsic silicon or may be doped with a p-type dopant such as boron or indium. In an alternative embodiment, the semiconductor substrate 300 may be doped with an n-type dopant such as phosphorous or antimony. The ONO layer may be created by forming a first oxide layer 305 on a surface of the substrate 300. The first oxide layer 305 may comprise, for example, silicon dioxide. A silicon nitride layer 310 may be formed on the first oxide layer 305, and a second oxide layer 315 may be formed on the silicon nitride layer 310. The first oxide layer 305 and the second oxide layer 315 should be thick enough to prevent the occurrence of electron tunneling between trapped electrons in the nitride layer 310 and bit or word lines, which may occur at a thickness less than about 50 angstroms (Å). In one embodiment, the first oxide layer 305 comprises silicon dioxide formed on the substrate to a thickness of about 50 to 100 Å using chemical vapor deposition (CVD), the silicon nitride layer 310 is formed using CVD to a thickness ranging from about 35 to 75 Å, and the second oxide layer 315 comprises silicon dioxide formed using CVD to a thickness of about 50 to 150 Å. In modified embodiments, one or more of these three layers may be grown. The ONO layer acts to trap charges within the nitride layer 310, which is electrically isolated by the second oxide layer 315 and the first oxide layer 305.

A layer of conductive material, which may comprise doped polysilicon, may then be deposited over the second oxide layer 315 at step 155. Gate structures may be created by patterning and etching the layer of conductive material at step 160. FIG. 4A illustrates a plan view of the gate structures 320, which take the form of parallel strips oriented in a bit line direction (i.e., a reference direction) after performance of step 160. FIG. 4B is a cross-sectional diagram taken along the line 4B-4B′ (i.e., along a direction perpendicular to the reference direction) of FIG. 4A.

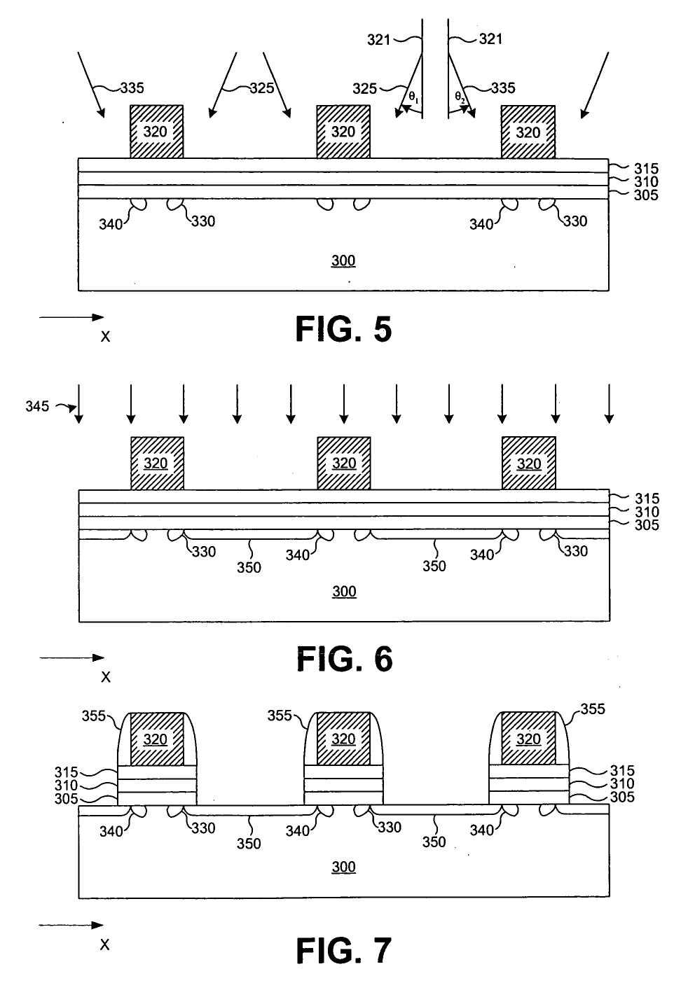

Turning to FIG. 5, a lightly doped p-type (i.e. a p−) implant 325 directed at a first tilt angle θ₁ with respect to a vertical component 321 may then be performed at step 165. The implant 325 passes through the ONO layer to create implant pockets 330 of p-type material in the substrate 300 at a location near the edge of the gates 320. Implant 335 having a second tilt angle θ₂ with respect to the vertical component 321 likewise may be performed at step 165, passing through the ONO layer and creating similar implant pockets 340 of p-type material in the substrate 300 at a location near an opposite edge of the gates 320. The value of second tilt angle θ₂ may be substantially opposite and equal to that of the first tilt angle θ₁, and may range from about 0° to about 25° in typical embodiments. In exemplary embodiments, a boron dose between about 10¹³ and about 10¹⁴ atoms/cm² can be employed at an energy level between about 15 and about 25 keV to form pockets 330 and 332. Alternatively, boron fluoride (BF₂) may be implanted with an energy ranging from about 40 to about 60 keV. The pocket implants 330 and 340 may in some implementations suppress an undesirable short channel effect as, for example, critical device dimensions decrease with successive process generations. Although such pocket implants may produce a serious hot carrier effect that can degrade oxide lifetime by producing relatively higher electric field intensity at channel edges, such an effect may in certain implementations be unexpectedly beneficial for operation of flash devices that employ hot electron programming. It should be noted that in certain implementations the process sequence or sequences described herein may be similar to normal CMOS process sequences.

As shown in FIG. 6, an n+ implantation 345 may then be performed at step 170, the implantation having a normal direction of incidence, passing through the ONO layer, and forming a shallow buried diffusion 350 near the surface of the substrate 300. In typical embodiments, arsenic at a dose between about 10¹³ and about 10¹⁵ atoms/cm² can be employed at an energy level between about 10 and about 20 keV to effectuate the n+ implantation 345.

At step 175 spacers such as oxide spacers 355 are then formed on sidewalls of the gates 320. According to an exemplary embodiment, the oxide spacers 355 may be formed by first depositing an oxide material, e.g., silicon dioxide or silicon nitride, on the exposed surfaces of the structure illustrated in FIG. 6. An anisotropic etch directed nominally at right angles to the surface of the substrate 300 may then be performed at step 180 to remove horizontal portions of the oxide material and exposed portions of the ONO layer. The result of performing the etch step 180 is illustrated in FIG. 7.

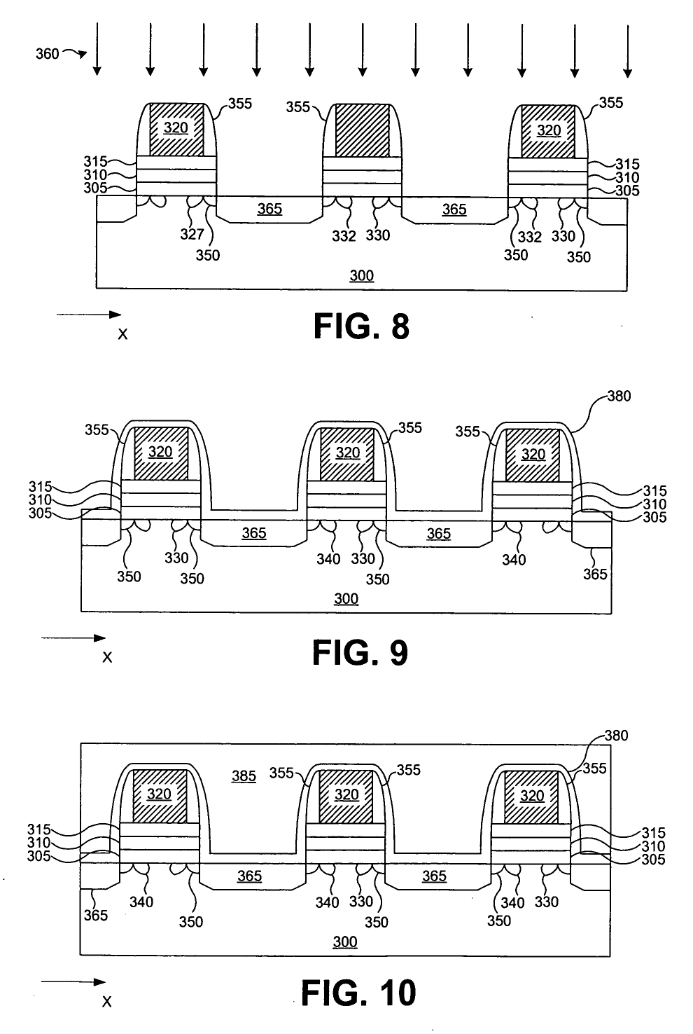

An n+ implantation 360 is then performed at step 185, wherein, as an example, n-type dopant such as phosphorous or antimony is implanted at a dose typically greater than about 10¹⁵ atoms/cm² using an implantation energy of about 10 to 20 keV. This implantation forms n+ type source/drain regions that may function as bit lines 365 in areas of the substrate 300 between gate structures 320 as illustrated in FIG. 8.

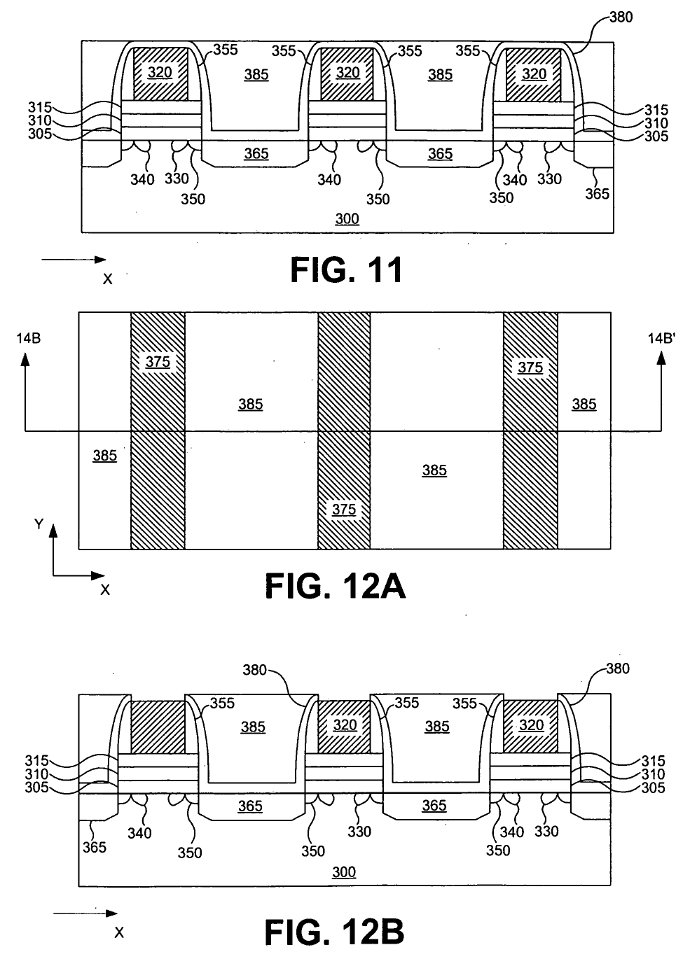

At step 205 a silicon oxynitride layer, designated by reference number 380 in FIG. 9, is deposited on exposed surfaces, and a silicon oxide, e.g., PEOX, 385, is deposited at step 210 as depicted in FIG. 10. A portion of the PEOX 385 is removed at step 215 using, for example, chemical mechanical polishing (CMP), halting the CMP process when a surface of the silicon oxynitride layer 380 is exposed as shown in FIG. 11.

The exposed silicon oxynitride material is then removed at step 220 by performing, for example, a selective anisotropic etch wherein the etchant has a greater selectivity for the silicon oxynitride layer 380 than for the PEOX 385.

FIG. 12A illustrates a plan view of the structure after the silicon oxynitride 380 has been removed. A cross-section of the structure taken along the line 14B-14B′ of FIG. 12A is shown in FIG. 12B.

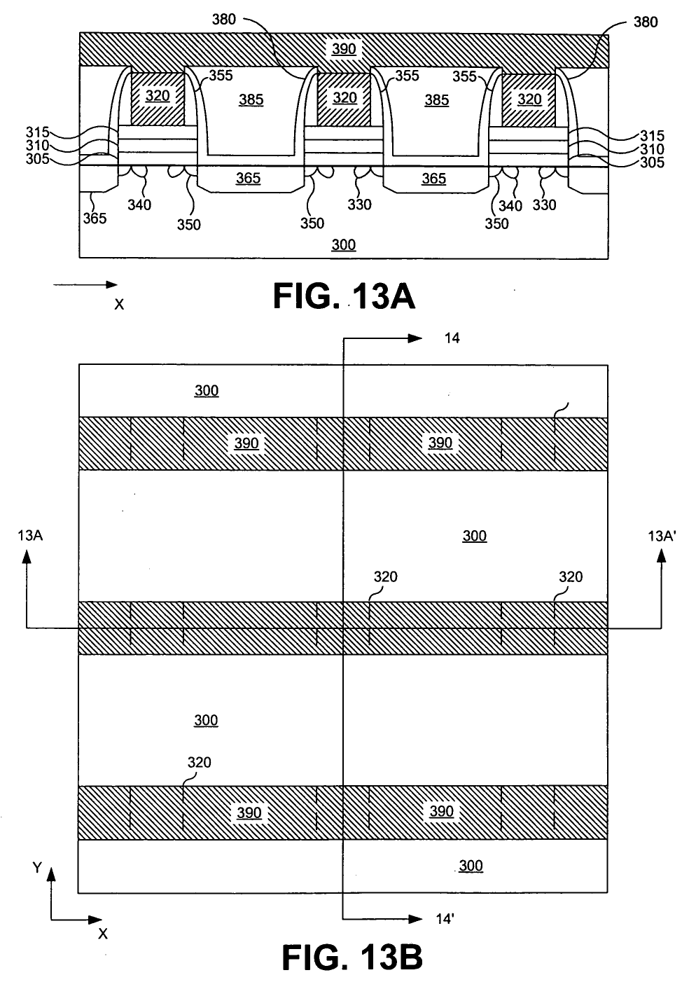

A second polysilicon layer is deposited at step 225, and a portion of the second polysilicon layer is then removed in the word-line direction (i.e., perpendicular to the reference direction) at step 230. FIG. 13A is a cross-sectional view illustrating the result following steps 225 and 230, wherein a portion of a second polysilicon layer 390 has been.

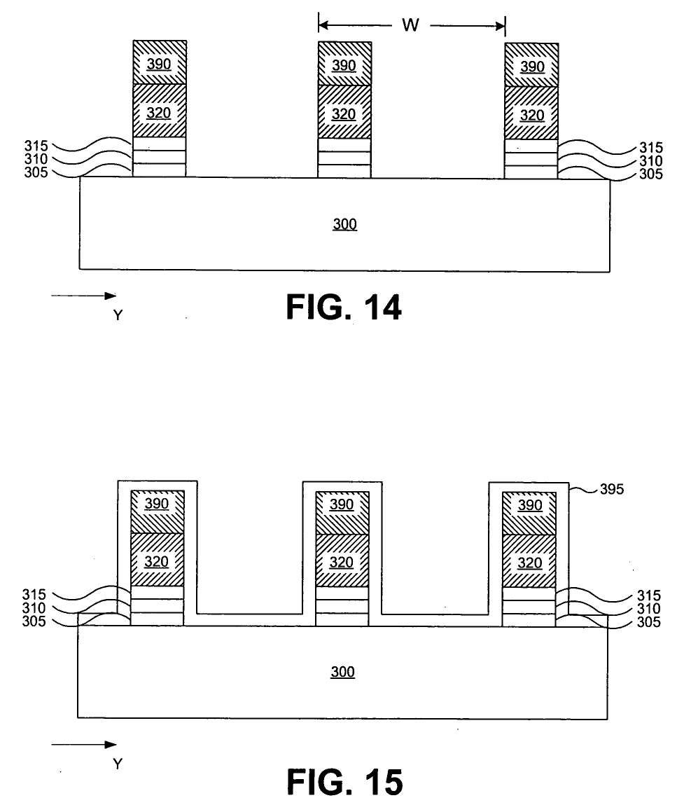

FIG. 13B provides a plan view of the structure of FIG. 13A, wherein the removal of a portion of the second polysilicon layer 390 (step 230) can be seen as well as line 13A-13A′ which defines the cross-sectional view of FIG. 13A. Individual memory cells, hidden but indicated by dashed lines in FIG. 13B, are nominally located under gate structures 320 at intersections of remaining portions of the second polysilicon layer 390 and remaining portions of the first polysilicon layer 320. An alternative cross-sectional view, taken along the line 14-14′ of FIG. 13B, is provided in FIG. 14. The removal of the portion of the second polysilicon layer 390 defines a cell width W according to the pitch of the memory cells shown in FIG. 14.

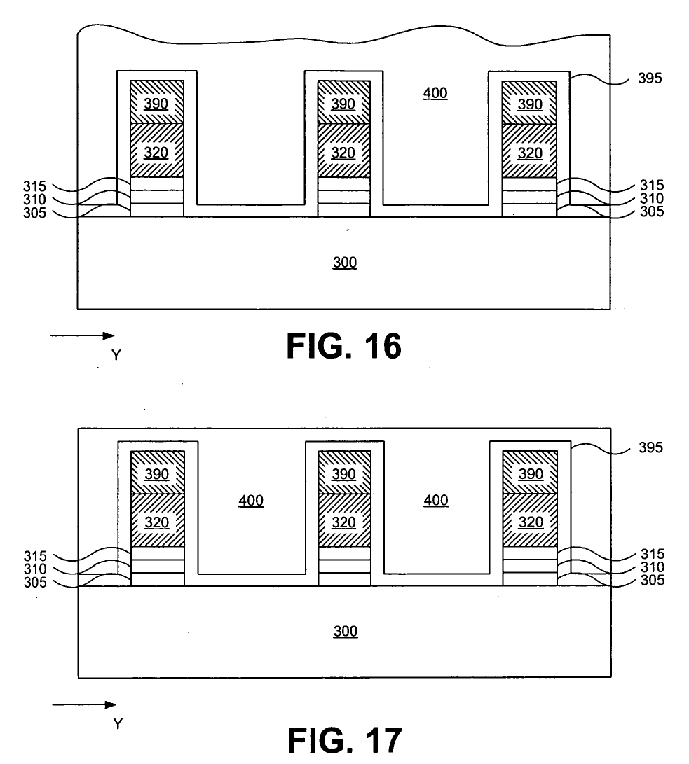

A layer of silicon oxynitride 395 is then deposited at step 235 as illustrated in FIG. 15. Also at step 235, an inter-layer dielectric (ILD) 400 is deposited, yielding the structure of FIG. 16. Part of the ILD 400 is removed by CMP at step 240 to generate the structure of FIG. 17. Subsequent process steps follow normal semiconductor fabrication procedures.

In view of the foregoing, it will be understood by those skilled in the art that the methods of the present invention can facilitate formation of read only memory devices, and in particular read only memory devices exhibiting dual bit cell structures, in an integrated circuit. The above-described embodiments have been provided by way of example, and the present invention is not limited to these examples. Multiple variations and modification to the disclosed embodiments will occur, to the extent not mutually exclusive, to those skilled in the art upon consideration of the foregoing description. Additionally, other combinations, omissions, substitutions and modifications will be apparent to the skilled artisan in view of the disclosure herein. Accordingly, the present invention is not intended to be limited by the disclosed embodiments, but is to be defined by reference to the appended claims.

What is claimed is:

1. A method for forming an array of trapped charge memory cells, comprising:
providing a semiconductor substrate having an oxide-nitride-oxide (ONO) layer formed on a surface thereof;
depositing a first layer of polysilicon over the ONO layer;
removing a portion of the first layer of polysilicon in a reference direction to form at least one gate structure, thereby exposing a portion of the ONO layer;
depositing an oxide spacer on sides of the at least one gate structure and on a portion of the ONO layer;
removing a portion of the ONO layer not covered by the oxide spacer to expose a portion of the substrate; and
forming at least one bit line in the exposed portion of the substrate.

2. The method as set forth in claim 1, wherein the removing of a portion of the first layer of polysilicon is followed by implanting with a tilt angle an implant pocket into the substrate through the ONO layer.

3. The method as set forth in claim 2, wherein the implanting comprises implanting with a tilt angle a plurality of implant pockets through the ONO layer into the substrate and at least partially beneath the at least one gate structure.

4. The method as set forth in claim 2, wherein the forming of at least one bit line comprises placing an implant into the exposed portion of the substrate;

5. The method as set forth in claim 4, wherein:
the forming of at least one bit line comprises forming at least one bit line comprising an n+ region in the exposed portion of the substrate;
the removing of a portion of the first layer of polysilicon is followed by implanting with a tilt angle a p− pocket into the substrate through the ONO layer; and
the placing of an implant comprises placing a p− implant into the exposed portion of the substrate.

6. The method as set forth in claim 4, further comprising:
depositing silicon oxynitride on the at least one gate structure and the oxide spacer;
depositing PEOX on the silicon oxynitride;
removing a portion of the deposited PEOX, stopping on the silicon oxynitride; and
removing a portion of the deposited silicon oxynitride to expose the at least one gate structure.

7. The method as set forth in claim 6, further comprising:
depositing a second layer of polysilicon on the silicon oxynitride and the at least one gate structure; and
removing portions of the second layer of polysilicon, the at least one gate structure, and the ONO layer in a direction perpendicular to the reference direction to define a width for at least one memory cell and to expose a portion of the substrate, the portion of the second layer of polysilicon not etched becoming part of the at least one gate structure.

8. The method as set forth in claim 7, further comprising:
depositing a layer of silicon oxynitride on the second layer of polysilicon, on the exposed portions of the substrate, and on sidewalls of the at least one gate structure;
depositing an inter-level dielectric (ILD) to form a flat surface overlying the at least one memory cell; and
removing a portion of the deposited ILD by chemical-mechanical polishing (CMP) and stopping on the silicon oxynitride.

9. The method as set forth in claim 8, further comprising:
forming a contact with the at least one gate structure;
depositing a metal layer; and
removing a portion of the metal layer to define at least one word line that connects to the at least one gate structure along the direction perpendicular to the reference direction.

10. A method for forming an array of trapped charge memory cells, comprising:
providing a semiconductor substrate having an oxide-nitride-oxide (ONO) layer formed on a surface thereof;
depositing a first layer of polysilicon over the ONO layer;
removing a portion of the first layer of polysilicon in a reference direction to form at least one gate structure, thereby exposing a portion of the ONO layer;
implanting with a tilt angle at least one implant pocket into the substrate through the ONO layer;
depositing an oxide spacer on sides of the at least one gate structure and on a portion of the ONO layer;
removing a portion of the ONO layer not covered by the oxide spacer to expose a portion of the substrate; and
forming at least one bit line in the exposed portion of the substrate.

11. The method as set forth in claim 10, wherein the implanting comprises implanting with a tilt angle a plurality of implant pockets into the substrate through the ONO layer.

12. The method as set forth in claim 10, wherein the implanting comprises implanting with a tilt angle a p− pocket into the substrate through the ONO layer.

13. The method as set forth in claim 10, wherein the implanting comprises implanting with a tilt angle a plurality of p− pockets into the substrate through the ONO layer.

14. The method as set forth in claim 10, wherein the implanting comprises implanting with a tilt angle a plurality of implant pockets through the ONO layer into the substrate and at least partially beneath the at least one gate structure.

15. The method as set forth in claim 10, wherein the forming of at least one bit line comprises:
placing an n+ implant into the exposed portion of the substrate;
performing an NADP implantation into the exposed portion of the substrate; and
performing a pre-amorphizing implant into the exposed portion of the substrate.

16. The method as set forth in claim 15, further comprising:
depositing silicon oxynitride on the at least one gate structure, the oxide spacer, and the substrate;
depositing PEOX on the silicon oxynitride;
removing a portion of the deposited PEOX by chemical mechanical polishing (CMP), stopping on the silicon oxynitride; and
removing a portion of the deposited silicon oxynitride to expose the at least one gate structure.

17. The method as set forth in claim 16, further comprising:
depositing a second layer of polysilicon on the silicon oxynitride and the at least one gate structure; and
removing portions of the second layer of polysilicon, the at least one gate structure, and the ONO layer in a direction perpendicular to the reference direction to define a width for at least one memory cell and to expose a portion of the substrate, the portion of the second layer of polysilicon not etched becoming part of the at least one gate structure.

18. The method as set forth in claim 17, further comprising:
depositing a layer of silicon oxynitride on the second layer of polysilicon, on the exposed portions of the substrate, and on sidewalls of the at least one gate structure;
depositing an inter-level dielectric (ILD) to form a flat surface overlying the at least one memory cell; and
removing a portion of the deposited ILD by CMP.

19. The method as set forth in claim 18, further comprising:
forming a contact with the at least one gate structure;
depositing a metal layer; and
removing a portion of the metal layer to define at least one word line that connects to the at least one gate structure along the direction perpendicular to the reference direction.
